(19) United States
(12) Patent Application Publication
(10) Pub. No.: US 2008/0305247 A1
(43) Pub. Date: Dec. 11, 2008

(54) Method And Device For Converting Metallic Precursors Into Chalcopyrite Layers Of Cigss Solar Cells

(76) Inventors: Christian Von Klopmann, Berlin (DE); Nikolaus Meyer, Berlin (DE); Ilka Luck, Berlin (DE); Dieter Schmid, Berlin (DE); Alexander Meeder, Berlin (DE)

Correspondence Address: THELEN LLP, P.O. BOX 640640, SAN JOSE, CA, 95164-0640, US

(21) Appl. No.: 12/159,082

(22) PCT Filed: Dec. 22, 2006
(86) PCT No.: PCT/EP06/70178

§ 371 Date: Jul. 1, 2008

(30) Foreign Application Priority Data
Dec. 28, 2005 (DE) 10 2005 062 977.6

(51) Int. Cl. B05D 5/12; B05C 11/00

(52) U.S. Cl. 427/74; 118/712

(57) ABSTRACT

The invention relates to a method and a device for reacting metallic precursors with sulfur and/or selenium to chalcopyrite layers of CIGSS solar cells in a reaction chamber of an RTP furnace. The aim of the invention is to produce thin-layer solar modules. Said aim is achieved by introducing a substrate coated with the precursor as well as an amount of sulfur and/or selenium that is sufficient to carry out the reaction into a sealingly closable reaction box which is provided with at least one discharge valve that can be controlled from outside the reaction chamber. The reaction box is introduced into the reaction chamber of the RTP furnace, the reaction chamber is evacuated, the reaction box is heated to a predetermined temperature in the reaction chamber along with the substrate and is maintained at said temperature for a certain process time, the pressure in the reaction box being measured and being controlled via the at least one discharge valve during the process time.

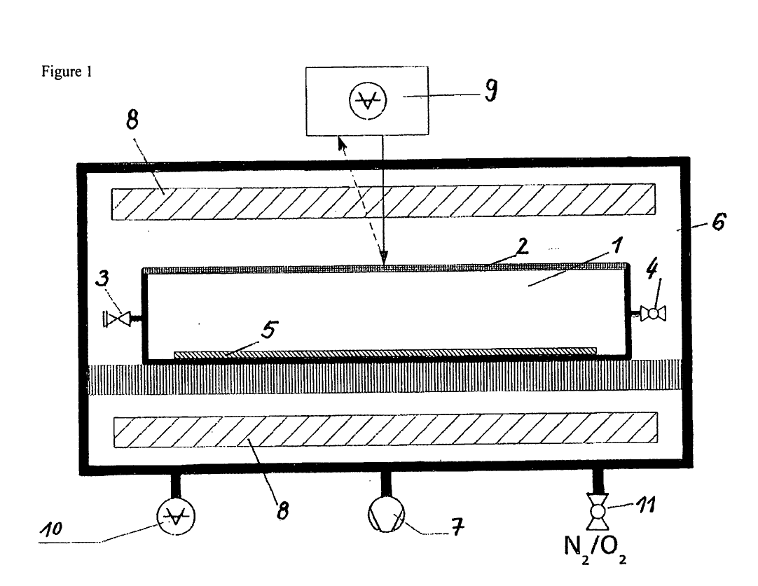

The invention relates to a method and a device for converting metallic precursor layers (hereinafter referred to as precursors) to chalcopyrite layers of CIGSS solar cells by reacting them with sulfur and/or selenium in a reaction chamber of an RTP oven. The goal is to produce thin-layer solar modules in particular.

Thin-layer solar cells with I-III-VI₂ chalcopyrite absorber layers, i.e., compounds of the form Cu(InₓGa₁₋ₓ)(Se_{y},S_{1-y})₂, where 0≦x≦1 and 0≦y≦1, hold the promise of inexpensive production and a high efficiency of the cells.

The precursors may preferably contain Cu and In/Ga or also Cu, Zn, Sn. They may also contain other elements, such as Ag, Sb, Sn, Zn or Fe.

The precursors may be thin layers (layer thicknesses 0.1 μm to 5 μm) on carrier substrates, which may be made of glass, ceramic, metal or plastics.

The carrier substrates may already be precoated with barrier layers to keep impurities from the glass away from the precursor. Such barrier layers may be silicon compounds, e.g., silicon nitrite.

The metallic precursor layers are reacted with an element of group VI, in the present case sulfur and/or selenium (hereinafter referred to as chalcogen). The conversion reaction (hereinafter referred to as reaction) takes place at elevated temperatures with an input of energy in a so-called RTP (rapid thermal processing) oven.

A chalcogen supply of precursors with gaseous chalcogen is known; the chalcogen is evaporated from the liquid phase in separate sources and introduced through suitable feed mechanisms into the reaction chamber, e.g., a selenium shower cell) (see, for example, Gabor et al., High-efficiency CuInₓGA₁₋ₓSe₂ solar cells made from (InₓGA₁₋ₓ)₂Se₃ precursor films, Appl. Phys. Lett. 65 (2), 1994, 198-200).

Methods that work with volatile compounds (H₂S or H₂Se) are also known. The volatile compounds are introduced into the reaction space by suitable feed mechanisms.

Furthermore, it is also customary to evaporate sulfur or selenium from vaporizer sources, e.g., Knudsen cells in a high vacuum.

Introduction of sulfur in solid form into the reaction space is also known (then powdered sulfur or sulfur flakes are placed next to the substrate in a petri dish).

The substrates coated with the precursor are introduced into a reaction space. The reaction space may have any shape and may be made of metal, glass or graphite, each of which may be coated or uncoated. The reaction space may have openings and valves (openings for loading and unloading—doors, flanges, vacuum slides) and may be evacuable (fine vacuum or high vacuum area).

The substrates with the precursor may be introduced directly into the reaction space in which they are placed on the bottom or are set vertically or horizontally or suspended in suitable holders.

According to DE 199 36 081 A1, a device and a method for tempering precursor layers in an RTP oven are known; according to this method, the coated substrate is introduced into a container having a bottom and a cover made of glass ceramic. The purpose of accommodating the substrate in the container is targeted energy input to the substrate from one side and to the precursor from the other side, such that the transparent covers of the container form filters for a preferred radiation source. However, the efficiency of the solar modules produced in this way is too low in comparison with what is theoretically feasible or with what has been achieved on a laboratory scale. Regarding the achievable values, see Siemer et al., Efficient CuInS₂ solar cells from a rapid thermal process (RTP), Solar Energy Materials and Solar Cells, 67 (2001), 159-166, and Probst et al., CIGSSe Module Pilot Processing: from Fundamental Investigations to Advanced Performance, WCPEC-3, Osaka, May 12-16, 2003.

The object of the invention is to provide a method and a device of the type defined in the introduction with which the efficiency of the solar cells produced thereby is further increased.

According to the invention the object is achieved by the features of claims 1 and 5. Expedient embodiments are the subject matter of the subclaims.

Accordingly, a substrate coated with the precursor and a sufficient amount of sulfur and/or selenium for the reaction is introduced into a reaction box, which can be closed with a seal and is provided with at least one outlet valve controllable from outside of the reaction box, and this reaction box is in turn introduced into the reaction space of the RTP oven. Then the reaction space is evacuated, whereby the reaction box is also evacuated and the reaction box is heated with the substrate in the reaction space to a predetermined temperature and is kept at this temperature for a certain process time. Separate evacuation of the reaction box is also conceivable. During the process time, the pressure in the reaction box is measured and controlled via the at least one outlet valve.

A suitable device for performing the method comprises a reaction box which is provided with at least one outlet valve controllable from outside the reaction chamber and which can be closed with a seal and can be charged with a substrate coated with the precursor and charged with an amount of sulfur and/or selenium sufficient for the reaction; the internal pressure of the reaction box can be measured with a sensor.

The reaction box may be made of metal, glass, ceramic or graphite. It may be coated or uncoated and transparent or opaque. The reaction box is tight, i.e., no gases escape from it into the reaction chamber during the reaction process and no gases penetrate from the reaction chamber into the reaction box. The reaction box contains valves to adjust the pressure before and during the process. In the process, the formation of destructive foreign phases is prevented with the targeted regulation of pressure, in particular regulation of the sulfur pressure.

The reaction box may be used directly for measurement of the process pressure by measuring the deformation of the cover of the reaction box.

As already stated, the reaction box is evacuated before the start of the process, i.e. before heating. Then a defined background pressure may be established with an inert gas in the box before the start of the reaction.

The supply of chalcogen (preferably sulfur and/or selenium) may be introduced
directly into the reaction space; to do so, a sufficient amount of chalcogen is made available in the reaction space;
directly into the reaction box; to do so, a sufficient amount of chalcogen is made available in the box;
by introducing powder, flakes, beads, tablets or some other solid form.

The chalcogen may be placed on the bottom of the reaction space or reaction box.

The chalcogen may also be introduced in boats, said boats optionally being open or partially closed. The boats may be made of graphite, glass, ceramic or metal; they may be coated or uncoated.

The amount of chalcogen is adapted to consumption during the reaction. Only as much chalcogen as is consumed by the layer during the reaction is added, so that sparse consumption is ensured; excess chalcogen would otherwise be deposited on the walls of the reaction chamber or reaction box and/or would be pumped out in the vacuum pumps of the reaction chamber.

The energy input for the reaction (conversion of the precursors to semiconducting chalcopyrite layers) may be accomplished via lamps mounted above and/or below the reaction box in the reaction chamber.

The energy input may also be accomplished via surface heating elements mounted in the reaction chamber or it may be accomplished via electric resistance heaters mounted in the reaction chamber.

The energy input is accomplished in a regulated manner so that the energy is made available according to the reactions taking place.

The advantages of this method are:
In contrast with methods known previously, the chalcogen is used very sparsely. Due to the direct introduction of defined quantities of chalcogen and the expected consumption by the reaction with the precursor layer, contamination of the reaction chamber and/or the reaction box and/or vacuum pumping can be largely prevented. The reaction box is sealed tightly, so that the chalcogen is available for the reaction and cannot escape into the surrounding reaction chamber or be pumped out by vacuum pumps. It has been customary in the past to work in more or less open systems, so sparse use of the process gas (the chalcogen) could not be guaranteed. Furthermore, great excess quantities were used and then could pollute the environment.
Due to the use of a reaction box and a reaction chamber, the reaction volume, i.e., the volume that must be heated and that comes in contact with the chalcogen may be kept very small. Furthermore, the reaction pressure can be adjusted in a defined manner by using a reaction box with pressure regulation and thus the reaction can be controlled in a targeted manner. The reaction of the metallic precursor layers to form semiconducting chalcopyrite runs through various chemical phases, which can be controlled and adjusted in a targeted manner via the pressure and temperature in the reaction box. This makes it possible to avoid unwanted byproducts of the reaction and to establish the desired reactions.
Through the use of a reaction box with an elastic cover, the pressure in the reaction box can be determined very accurately by the deformation of the cover. By coupling the pressure signal to regulation of the gas flow rate in the reaction chamber, the pressure in the reaction chamber can thus be adapted to the pressure in the reaction box. By controlling the valves of the reaction chamber and the reaction box, any desired pressure can be established in the reaction box during the reaction and varied in a targeted manner.
In contrast with the methods known in the past, nontoxic educts are used, and it is not necessary to use toxic hydrogen sulfide or hydrogen selenide compounds (H₂S or H₂Se). Furthermore, only the absolutely necessary amount of chalcogen is used, because in a closed system the chalcogen cannot escape and can be consumed completely in the reaction.
The loading and unloading of the reaction space with reaction boxes which can be filled with precursors and chalcogen outside of the reaction chamber, a high degree of automation is required.

The invention will now be explained in greater detail below on the basis of an exemplary embodiment. The respective drawing shows a reaction box that is used for the method, installed in a reaction chamber of an RTP oven, shown here in cross section.

The reaction box 1 is a shallow graphite box with a transparent cover 2 made of glass ceramic. The reaction box 1 is sealed against the cover 2 with a high-temperature-resistant gasket. A valve block containing excess pressure valves 3 and a controllable valve 4 by means of which the desired pressure can be set and controlled by the software during the process is located at each end of the reaction box.

The cover 2 is removed for loading and unloading the reaction box 1.

The reaction box 1 is assembled with a carrier substrate 5 made of glass from which a solar module is fabricated after the process. The carrier substrate 5 is coated with molybdenum (0.1 μm to 2 μm layer thickness), copper (0.1 μm to 2 μm layer thickness) and indium (0.1 μm to 2 μm layer thickness), for example. In addition to the coated carrier substrate 5, sulfur in elemental form is also added to the reaction box 1.

The reaction box 1 is sealed with the transparent cover 2 and then placed in a reaction chamber 6 of an RTP oven.

The reaction box 1 is evacuated by means of a vacuum pump 7, then the controllable valve 4 is closed and the reaction box 1 is heated. The heating is performed in the reaction chamber of the RTP oven with quartz lamps 8 mounted above and below the reaction box 1 in the reaction chamber 6. The reaction box 1 is heated from room temperature to the process temperature (300° C. to 600° C.) during the process. The heating process takes between 1 minute and 60 minutes. During the heating process, the prevailing pressure in the reaction box 1 is measured continuously. The bending of the elastic cover 2 is detected visually by a sensor 9. In addition, the pressure in the reaction chamber 6 can be measured by a pressure sensor 10. During the heating process, specific pressure profiles are adjusted and maintained over the entire course.

Before the start of the process, defined pressures (between 0.1 and 100 hPa) are set in the reaction box 1 via the supply of inert gas through a valve 11.

During the process time, the precursor layers (copper and indium on molybdenum) pass through defined phases. The precursor reacts with sulfur to form CuInS₂ and Cu₂S/CuS by way of the intermediate phases CuIn₂, Cu₁₁In₉ and Cu₁₆In₉. The temperature profile and especially the pressure profile are adjusted, so that only the desired products (CuInS₂ and Cu₂S/CuS) are formed from the educts and no compounds can occur between In and S. Furthermore, the formation of In-rich phases in the CuInS system (e.g., CuIn₆S₈) is prevented.

By heating the reaction box, both the carrier substrate 5 with the precursor layers and the added elemental sulfur are heated. The elemental sulfur is converted first to the liquid phase and then to the gaseous phase. The boiling point of sulfur can be adjusted accurately by means of the previously adjusted inert gas pressure. The maximum pressure buildup in the reaction box is determined by the amount of added sulfur and a set temperature of the reaction box 1. By opening the controllable valve 4 during the process, the process pressure can be adjusted to the desired levels.

After the end of the reaction of the precursors to CuInS₂, the quartz lamps 7 are turned off and the reaction box 1 is cooled to room temperature. The excess sulfur is pumped out after opening the controllable valve 4 in the reaction chamber 6. The required amount of sulfur depends exclusively on the layer thickness of the precursor and may be determined accurately to less than 30% excess, or even much less in practical terms. This ensures gentle handling of the resources (the starting amount of process substances here).

### LIST OF REFERENCE NUMERALS

1 reaction box
2 cover
3 excess pressure valve
4 controllable valve
5 carrier substrate
6 reaction chamber
7 vacuum pump
8 quartz lamp
9 sensor
10 pressure sensor
11 valve

1. Method for reacting metallic precursor layers (precursors) with sulfur or selenium to yield chalcopyrite layers of CIGSS solar cells in a reaction chamber of an RTP oven, wherein
a substrate coated with the precursor and a sufficient amount of sulfur or selenium for the reaction are placed in a reaction box that can be sealed tightly and is provided with at least one outlet valve controllable from outside the reaction chamber, said reaction box in turn being introduced into the reaction space of the RTP oven, the reaction space being evacuated, the reaction box being heated to a predetermined temperature with the substrate in the reaction space and kept at this temperature for a certain process time, whereby the pressure in the reaction box is measured during the process time and is controlled via the at least one outlet valve.

2. Method according to claim 1, wherein the heating process takes place under an inert gas.

3. Method according to claim 1, wherein sulfur or selenium in solid form is introduced into the reaction box.

4. Method according to claim 1, wherein the amount of sulfur or selenium exceeds the amount needed for the reaction by no more than 30%.

5. Device for reacting metallic precursor layers (precursor) with sulfur or selenium to form chalcopyrite layers of CIGSS solar cells in an RTP oven, wherein
a reaction box which is equipped with at least one outlet valve controllable from outside the reaction chamber is provided, its internal pressure being measurable with a sensor, and which can be tightly sealed and can be charged with a substrate coated with the precursor and with an amount of sulfur and/or selenium sufficient for the reaction.

6. Device according to claim 5, wherein the cover of the reaction box is transparent.

7. Device according to claim 5, wherein the cover of the reaction box is elastic.

8. Device according to claim 5, wherein the cover of the reaction box is made of glass ceramic.

9. Device according to claim 5, wherein the cover is provided with a high-temperature-resistant gasket with respect to the housing of the reaction box.

10. Device according to claim 5, wherein the reaction box is additionally provided with at least one excess pressure valve.

11. Device according to claim 5, wherein the sensor for measuring the internal pressure of the reaction box is an optical sensor that measures the bending of the cover.

12. Device according to claim 5, wherein the sensor for measuring the internal pressure of the reaction box is connected to a regulator for the gas flow through the reaction box.

13. Device according to claim 5, wherein heating lamps are arranged in the reaction chamber above and/or below the reaction box.

14. Device according to claim 5, wherein the reaction chamber is equipped with an additional pressure sensor.
